(19) United States
(12) Patent Application Publication
(10) Pub. No.: US 2009/0150595 A1
(43) Pub. Date: Jun. 11, 2009

(54) BALANCED PROGRAMMING RATE FOR MEMORY CELLS

(76) Inventor: Avi Lavan, Yokneam-Elit (IL)

Correspondence Address: EMPK & Shiloh, LLP;c/o Landon IP, Inc., 1700 Diagonal Road, Suite 450, Alexandria, VA, 22314, US

(21) Appl. No.: 11/877,798

(22) Filed: Oct. 24, 2007

(51) Int. Cl. G06F 12/02; G06F 12/00; G11C 11/34

(52) U.S. Cl. 711/103; 365/185.01; 711/E12.001; 711/E12.008

(57) ABSTRACT

A balanced program rate on NVM cells is achieved by (i) scrambling data bits and user bits; and (ii) shifting ED bits (of data and user bits) according to an incremental shift number, which may be the PBE-counter (which provides an incremental number). ED bits for the LSS may also be shifted, according to an incremental shift number (which may be the PBE-counter). The ED bits of the shift-niumber inherently have an evenly balanced distribution The ED bits of the PBE-counter inherently have an evenly balanced distribution.

### TECHNICAL FIELD

This disclosure relates to non-volatile memory (NVM) cells, such as nitride read only memory (NROM) and other ONO (oxide-nitride-oxide) cells and other microelectronic devices and structures and, more particularly, to modes of operating (particularly erasing and progranling) NROM cells.

### BACKGROUND

Demand for non-volatile memory (NVM) devices, including embedded NVM in other microelectronics and IC devices, has grown rapidly in recent years due to the expansion of digital computing and processing beyond desktop computer systems to include a broader array of consumer electronic, communications, automotive and industrial products. These products include mobile phones, still and video digital cameras, personal digital assistants (PDAs), portable computers, portable digital music players, digital video recorders, set-top boxes, communication routers and switches, digital televisions and other electronic systems. Each of these products typically requires one or more non-volatile memory device(s) to store data, such as the product's operating system and may also require data storage capabilities. The flash memory market, which in 2004 was the largest segment of the non-volatile semiconductor memory market, has traditionally been divided into four segments: code flash, data flash, embedded flash and serial flash.

Historically, the most widely-used tecldniology for non-volatile semiconductor memory devices is floating gate technology, which was developed in the late 1960s and has been the prevalent teclmology for non-volatile semiconductor memory devices since then. A floating gate device is a variation of a standard metal oxide semiconductor (MOS) field effect transistor (FET) in that it has an additional electrically isolated “floating gate,” made of a conductive material. A floating gate device stores information by holding electrical charge within the floating gate Adding or removing charge from the floating gate changes the threshold voltage (Vt) of the cell thereby defining whether the memory cell is in a programmed or erased state—representing a binary “1” or a binary “0” (memory cell states which may also be referred to herein as logic “1” and logic “0”), respectively or, conversely, binary or logic “0” and binary or logic “1”, respectively (the definition of the erase and program states as binary or logic “1” and binary or logic “0” being somewhat arbitrary, and generally at a designer's/manufacturer's discretion).

NROM technology effectively doubles the storage capacity of each memory cell by enabling the storage of two physically distinct and independent charges, each representing one bit of information, within a single memory cell. This significantly reduces the amount of silicon wafer required for each non-volatile memory device, resulting in a significant cost reduction to semiconductor manufacturers. Further advances in NROM and related ONO teclinology increase storage capacity to more than two bits (binary digits) per cell by better control and/or characterization of trapped charge.

Non-volatile memory devices based on NROM or other ONO (such as SONOS) technology contain a trapping nitride layer which stores a charge, instead of a floating gate suspended above the cell The nitride layer is usually surrounded by two insulating silicon dioxide layers (oxide). Where applicable, descriptions involving NROM are intended specifically to include related oxide-nitride technologies, including SONOS (Silicon-Oxide-Nitride-Oxide-Silicon), MNOS (Metal-Nitride-Oxide-Silicon), MONOS (Metal-Oxide-Nitride-Oxide-Silicon) and the like used for NVM devices. Further description of NVM and related technologies may be found at “Non Volatile Memory Teclnology”, 2005 published by Saifun Semiconductor; “Microchip Fabrication”, by Peter Van Zant, 5^{th} Edition 2004; “Application-Specific Integrated Circuits” by Michael Joln Sebastian Smith, 1997; “Semiconductor and Electronic Devices”, by Adir Bar-Lev, 2^{nd} Edition, 1999; “Digital Integrated Circuits” by Jan M. Rabaey, Anantha Chandrakasan and Borivoje Nikolic, 2^{nd} Edition, 2002 and materials presented at and through http://siliconnexus.com, “Design Considerations in Scaled SONOS Nonvolatile Memory Devices” found at: http:;//klabs.org/richcontent/MemoryContent/nvmt_symp/nvmts_2000/pesentations/bu white_sonos_lehigh_univ.pdf, “SONOS Nonvolatile Semiconductor Memories for Space and Military Applications” found at: http://klabs.org/riclhcontent/MemolyContent/nvmt_symp/nvmts_2000/papers/adams_d.p df, “Philips Research—Technologies—Embedded Nonvolatile Memories” found at: http://research.pilips.com/technologies/ics/nvmemories/index.html, and “Semiconductor Memory: Non-Volatile Memory (NVM)” found at: http://ece.nus.edu.sg/stfpage/elezlhucx/myweb/NVM.pdf, all of which are incorporated by reference herein in their entirety.

Commonly-owned patents disclose structure and operation of NROM and related ONO memory cells. Some examples may be found in commonly-owned U.S. Pat. Nos. 5,768,192 and 6,011,725, 6,649,972 and 6,552,387.

Commonly-owned patents disclose architectural aspects of an NROM and related ONO array, (some of which have application to other types of NVM array) such as segmentation of the array to handle disruption in its operation, and symmetric architecture and non-symmetric architecture for specific products, as well as the use of NROM and other NVM array(s) related to a virtual ground array. Some examples may be found in commonly-owned U.S. Pat. Nos. 5,963,465, 6,285,574 and 6,633,496.

Commonly-owned patents also disclose additional aspects at the architecture level, including peripheral circuits that may be used to control an NROM array or the like. Some examples may be found in commonly-owned U.S. Pat. Nos. 6,233,180, and 6,448,750.

Commonly-owned patents also disclose several methods of operation of NROM and similar arrays, such as algorithms related to programming, erasing, and/or reading such arnays. Some examples may be found in commonly-owned U.S. Pat. Nos. 6,215,148, 6,292,394 and 6,477,084.

Commonly-owned patents also disclose manufacturing processes, such as the process of forming a thin nitride layer that traps hot electrons as they are injected into the nitride layer Some examples may be found in commonly-owned U.S. Pat. Nos. 5,966,603, 6,030,871, 6,133,095 and 6,583,007.

Commonly-owned patents also disclose algorithms and methods of operation for each segment or teclnological application, such as: fast programming methodologies in all flash memory segments, with particular focus on the data flash segment, smart programming algorithmis in the code flash and electrically erasable programmable read only memory (EEPROM) (also E2PROM) segments, and a single device containing a combination of data flash, code flash and/or EEPROM. Some examples may be found in commonly-owned U.S. Pat. Nos. 6,954,393 and 6,967,896.

The Field Effect Transistor

The transistor is a solid state semiconductor device which can be used for amplification, switching, voltage stabilization, signal modulation and many other functions, Generally, a transistor has three terminals, and a voltage applied to a specific one of the terminals controls current flowing between the other two terminals.

The terminals of a field effect transistor (FSET) are commonly named source, gate and drain In the FET a small amount of voltage is applied to the gate in order to control current flowing between the source and drain. In FETs the main current appears in a narrow conducting channel formed near (usually primarily under) the gate. This channel connects electrons from the source terminal to the drain terminal. The channel conductivity can be altered by varying the voltage applied to the gate terminal, enlarging or constricting the channel and thereby controlling the current flowing between the source and the drain.

FIG. 1 illustrates a FET 100 comprising a p-type substrate, and two spaced-apart n-type diffusion areas—one of which will serve as the “source”, the other of which will serve as the “drain” of the transistor. The space between the two diffusion areas is the “channel”. A thin dielectric layer is disposed over the substrate in the neighborhood of the channel, and a “gate” structure is disposed over the dielectric layer atop the channel. (The dielectric under the gate is also commonly referred to as “gate oxide” or “gate dielectric”). Electrical connections (not shown) may be made to the source, tme drain, and the gate. The substrate may be grounded.

Generally, when there is no voltage on the gate, there is no electrical conduction (connection) between the source and the drain. As voltage (of the correct polarity) is applied to the gate, there is a “field effect” in the channel between the source and the drain, and curTent can flow between the source and the drain, and can be controlled by the voltage applied to the gate. In this manner, a small signal (gate voltage) can control a relatively large signal (current flow between the source and the drain).

### The Floating Gate Transistor Memory Cell

A floating gate transistor is generally a transistor structure, broadly based on the FET, as described hereinabove. As illustrated in FIG. 2, the floating gate transistor 200 has a source and a drain, but rather than having only one gate, it has two gates which are called control gate (CG) and floating gate (FG). It is this arrangement of control gate and floating gate which enables the floating gate transistor to function as a memory cell, as described hereinbelow.

The floating gate is disposed over tunnel oxide (comparable to the gate oxide of the FET). The floating gate is a conductor, the tunnel oxide is an insulator (dielectric material). Another layer of oxide (interpoly oxide, also a dielectric material) separates the floating gate from the control gate.

Since the floating gate is a conductor, and is surrounded by dielectric material, it can store a charge. Electrons can move around freely within the conductive material of the floating gate (which comports with the basic definition of a “conductor”).

Since the floating gate can store a charge, it can exert a field effect on the channel region between the source and the drain, in a manner similar to how a normal FET works, as described hereinabove. Mechanisms for storing charges on the floating gate structure, as well as removing charges fioni the floating gate are described hereinbelow.

Generally, if a charge is stored on the floating gate, this represents a binary “1”. If no charge is stored on the floating gate, this represents a binary “0”. (These designations are arbitrary, and can be reversed so that the charged state represents binary “0” and the discharged state represents binary “11”). That represents the programming “half” of how a floating gate memory cell operates The other half is how to determine whether there is a charge stored on the floating gate—in other words, to “read” the memory cell. Generally, this is done by applying appropriate voltages to the source, drain and gate terminals, and determining how conductive the channel is. Some modes of operation for a floating gate memory cell are described hereinbelow.

Nonnally, the floating gate non-volatile memory (NVM) cell has only a single “charge-storing area”—namely, the conductive floating gate (FG) structure, and using traditional single level cell (SLC) tecl-miques can only store a single bit of information (binary “1” or binary “0”). More recently, using a technology referred to as “multi-level cell” (MLC), two or more bits can be stored in and read from a single floating gate cell, MLC operation of memory cells is discussed in greater detail hereinbelow

### Multi-Level Cell (MLC) Operation of Memory Cells

Mention has been made, hereinabove, of single level cell (SLC) and multi-level cell (MLC) operation, and it shall be described only briefly in this disclosure.

Theoretically, in order to determine the programmed state of a memory cell, only one voltage threshold is needed—either the threshold voltage (Vt) of the cell is below the threshold, or over the threshold (Vth). However, this simplistic approach can lead to ambiguities and false readings. This is in part due to the fact that the charges (such as electrons) cannot be stored (in the floating gate, or in the NROM storage region) with absolute precision, and is in part due to the fact that sometimes electrons disappear from the storage region.

Therefore, in practice, to store one bit of data, two voltage levels are needed. If the sensed threshold voltage is below the lower of the two voltage levels, that is classified as a “0”, and if the sensed threshold voltage is above the higher of the two voltage levels, that is classified as a “1”.

Memory cell technology has been developed wherein memory cells can hold two or more bits of data, instead of just one each, in the storage region. The trick is to take advantage of the analog nature of the charge stored in the memory cell and allow it to charge to several different voltage levels. Each voltage range to which the floating gate can charge can then be assigned its own digital code. This is generally referred to as “Multi-Level Cell (MLC)” technology.

### A Two-Bit (Dual Bit) NROM Memory Cell

Another type of memory cell, called a “initride, read only memory” (NROM) cell, has a charge-storage structure which is different from that of the floating gate memory cell and which permits charges to be stored in two separate charge-storage areas. Generally, the two separate charge storage areas are located within a non-conductive layer disposed between the gate and the underlying substrate, such as a layer of nitride formed in an oxide-nitride-oxide (ONO) stack underneath the gate. The non-conductive layer acts as a charge-trapping medium. Generally, electrical charges will stay where they are put in the charge-trapping medium, rather than being free to move around as in the example of the conductive floating gate of the floating gate memory cell. A first bit of binary information (binary “1” or binary “0”) can be stored in a first portion (such as the left-hand side, or “half cell”) of the charge-trapping medium, and a second bit of binary information (binary “1” or binary “0”) can be stored in a second portion (such as the right-hand side, or “half cell”)) of the chaarge-trapping medium. An alternative viewpoint is that different charge concentrations can be considered for each bit of storage. Using MLC technology, at least two bits can be stored ill and read from each of the two portions of the charge-trapping medium (for a total of 4 bits), similarly 3 bits or more than 4 bits may be identified.

FIG. 3 illustrates a basic NROM memory cell 300, which may be viewed as a FET with an “ONO” structure inserted between the gate and the substrate. (One might say that the ONO structure is “substituted” for the gate oxide of the FET).

The ONO structure is a stack (or “sandwich”) of lower oxide 322, a charge-trapping material such as nitride 324, and an upper oxide 326. The ONO structure may have an overall thickness of approximately 10-25 nm, such as 18 nm, as follows:
the bottom oxide layer 322 may be from 3 to 6 run, for example 4 nm thick;
the middle nitride layer 324 may be from 3 to 8 nm, for example 4 nm thick; and
the top oxide layer 326 may be fiom 5 to 15 nm, for example 10 nm thick.

The NROM memory cell has two spaced apart diffusions 314 and 316 (which can function as source and drain, as discussed hereinbelow), and a channel region 320 defined in the substrate 312 between the two diffusion regions 314 and 316, and a gate 328 disposed above the ONO stack 321.

The charge-trapping material 324 is non-conductive, and therefore, although electrical charges can be stored in the charge-trapping material, they are not free to move around, they will generally stay where they are stored. Nitride is a suitable charge-trapping material. Charge trapping materials other than nitride may also be suitable for use as the charge-trapping medium. One such material is silicon dioxide with buried polysilicon islands. A layer (324) of silicon dioxide with polysilicon islands would be sandwiched between the two layers of oxide (322) and (326). Alternatively, the charge-trapping layer 324 may be constructed by implanting an impurity, such as arsenic, into a layer of silicon dioxide deposited on top of the bottom oxide 322.

The memory cell 300 is generally capable of at least two bits of data, at least one bit in an area of the nitride layer 324 represented by the dashed circle 323 and at least one bit in an area of the nitride layer 324 represented by the dashed circle 321. These two storage (charge-trapping) areas 321 and 324 may be referred to as “half cells”.

Each of the storage areas 321, 323 in the charge-trapping material 324 can exert a to field effect on the channel region 320 between the source and the drain, in a manner similar to how a normal FET works, as described hereinabove (FIG. 2). Some mechanisms for storing in the storage areas of the charge-trapping material, as well as removing charges from the storage areas of the charge-trapping material are described hereinbelow.

Generally, if a charge is stored in a given storage area of the charge-trapping material, this represents a binary “1”, and if no charge is stored in a given storage area of the charge-trapping material, this represents a binary “0”. (These designations are arbitrary, and can be reversed so that the charged state represents binary “0” and the discharged state represents binary “1”). That represents the programming “half” of how an NROM memory cell operates. The other half is how to determine whether there is a charge stored in a given storage area of the charge-trapping material—in other words, to “read” the memory cell. Generally, this is done by applying appropriate voltages to the diffusion regions (functioning as source and drain) and gate terminals, and determining how conductive the channel is. Some modes of operation for an NROM memory cell are described hereinbelow.

Generally, one feature of NROM cells is that rather than performing “symmetrical” programming and reading, NROM cells are beneficially programmed and read “asymmetrically” which means that programnming and reading occur in opposite directions. The arrows labeled in FIG. 3 are arranged to illustrate this point.

Programming may be performed in what is termed the “forward” direction and reading may be performed in what is termed the “opposite” or “reverse” direction. Some programming and reading modes of operation for memory cells are described hereinbelow.

### Memory Cell Modes of Operation and Injection Mechanisms

A memory cell's state may be defined and determined by what is called its threshold voltage (Vt) which determines a threshold level for the gate voltage required to establish the “channel” between the source and the drain—in other words, for the memory cell to begin to conduct current. A memory cell's threshold voltage level is directly related to the amount of charge (the number of electrons) stored in the charge storage region (floating gate, or ONO layer) of the cell—generally, more electrons stored means a higher threshold voltage Vt. Typically, for a given structure of a memory cell, the gate voltage that provides 1 pA (picoAmpere) of channel current is termed the threshold voltage (Vt).

The structure and general operation of two types of memory cells—floating gate and NROM—have been described hereinabove, with reference to FIG. 2 (floating gate) and FIG. 3 (NROM). Fundamentally, these two types of memory cells have in common with one another that they both operate very generally as a field effect transistor (FET)—namely, having two spaced-apart diffusion regions (functioning as source and drain) and a gate (for controlling the flow of electrons (current) through the channel region between the two diffusion areas, with the modification that they both have a charge storage structures under the gate.

The floating gate (FG) memory cell has a conductive layer between the gate and the channel region and, since the floating gate is a conductor, electrical charges stored in the floating gate are free to move around within the floating gate.

The NROM memory cell has a non-conductive layer (such as nitride) which can store charge in distinct areas and, since the non-conductive layer is not a conductor, the charges stored in the non-conductive layer are not free to move around, but rather tend to stay more-or less where they have been stored in a charge-storage region of the non-conductive layer, typically in a first region near one of the two diffusion regions, and in a second region adjacent the other of the two diffusion regions. These two diffusion regions are typically referred to as “left” and “right”, and the corresponding two charge-storage regions in the non-conductive layer are typically similarly referred to as “left” and “right”.

It is sufficient, for purposes of this disclosure, to understand that elemental electrical “charges” such as electrons and holes can be injected into the charge-storage structure or areas of memory cells, The charges can also be removed from the charge-storage structure or areas. Generally, the process of moving of charges into or out of the charge-storage structure is referred to as “injection”, and there are a number of known injection mechanisms.

The broad purpose of semiconductor memory is to store (“program”) data—many binary “1”s and “0”s—and allow access to (“read”) the stored data. The broad purpose of a single memory cell is to store individual bits of the data. Single-level (SLC) floating gate memory cells can store one bit of data. Single-level (SLC) NROM memory cells can store two bits of data. Multi-level (MLC) floating gate memory cells can store two (or more) bits of data. Multi-level (MLC) NROM memory cells can store four (or more) bits of data.

Data is stored in and retrieved from memory cells in what is termed “modes of operation”. Generally, there are four modes of operation: “erase”, “program”, “write” and “read”. The first three modes (erase, program, write) relate to storing data. And, for purposes of this discussion, the write mode typically is simply a combination of erase and program. The read mode refers to accessing stored data.

There are, of course, many nuances to each of the operations of memory cells discussed hereinabove. For example, repeated erasing of a memory cell can result in lowering the threshold voltage beyond zero, becoming negative, a condition known as “over-erase”. Similarly, repeated programming of a memory cell can result in the accumulation of so many electrons that an erase operation will not be able to sufficiently lower the tlireshold voltage below the erase level—this is referred to as “over-programming”. (In these two examples, it is assumed that program is to a high threshold voltage, and erase is to a low tlueshold voltage. In some cases, these two situations may be reversed by erasing to a high tlneshold voltage and programming to a low threshold voltage).

Programming is typically performed in increments, with pulses of voltage—after each pulse, a verify operation occurs in which the threshold voltage level Of the cell is measured (read). The general idea is to “nudge” the threshold voltage to the desired level, rather than over-shooting (over programming) or under-shooting (under programming) the desired level. With appropriate control mechanisms, only a few pulses (nudges) are required. A similar concept of cycles of pulse followed by verify until a desired Vt has been attained may sometimes be used during the erase operation, to avoid under-erase or over-erase. See, for example, commonly-owned U.S. Pat. Nos. 6,292,394; 6,396,741; 6,490,204; 6,552,387; 6,636,440; and 6,643,181.

### Memory Array Architecture, Generally

Memory ayrays are well known, and comprise a plurality (many, including many millions) of memory cells organized (including physically arranged) in rows (usually represented in drawings as going across the page, horizontally, from left-to-right) and columns (usually represented in drawings as going up and down the page, from top-to-bottom).

As discussed hereinabove, each memory cell comprises a first diffusion (functioning as source or drain), a second diffusion (functioning as drain or source) and a gate, each of which has to receive voltage in order for the cell to be operated, as discussed hereinabove. Generally, the first diffusions (usually designated “source”) of a plurality of memory cells are connected to a first bit line which may be designated “BL(n)”, and second diffusions (usually designated “drain”) of the plurality of memory cells are connected to a second bit line which may be designated “BL(n+1)”. Typically, the gates of a plurality of memory cells are connected to common word lines (WL).

FIG. 4 illustrates an airay of NROM memory cells (labeled “a” through “i”) connected to a number of word lines (WL) and bit lines (BL). For example, the memory cell “e” has its gate connected to WL(n), its source (left hand diffusion) is connected to BL(n), and its drain (right hand diffusion) is connected to BL(n+1). The nine memory cells illustrated in FIG. 4 are exemplary of many millions of memory cells that may be resident on a single chip.

Notice, for example that the gates of the memory cells “e” and “f” (to the right of “e”) are both connected to the same word line WL(n). (The gate of the memory cell “d” to the left of “e” is also connected to the same word line WL(n)). Notice also that the right hand terminal (diffusion) of memory cell “e” is connected to the same bit line BL(n+1) as the left-hand terminal (diffusion) of the neighboring memory cell “f”. In this example, the memory cells “e” and “f” have two of their three terminals connected together.

A memory anray may also include isolation zones (not shown). Isolation zones segregate one group of memory cells from a neighboring group of memory cells; for example, isolation zones can divide the array into slices of just one column or a plurality of columns. Examples of arrays having isolation zones may be found in commonly-owned U.S. Pat. No. 7,043,672, incorporated in its entirety by reference herein, and in commonly-owned U.S. Pat. No. 6,975,536.

A more complete description of NROM and similar ONO cells and devices, as well as processes for their development may be found at “Non Volatile Memory Technology”, 2005 published by Saifun Semiconductor and materials presented at and through http://siliconnexus.comn, both incorporated by reference herein in their entirety.

### Glossary

Unless otherwise noted, or as may be evident from the context of their usage, any terms, abbreviations, acronyms or scientific symbols and notations used herein are to be given their ordinary meaning in the teclnical discipline to which the disclosure most nearly pertains. The following terms, abbreviations and acronyms may be used throughout the descriptions presented herein and should generally be given the following meaning unless contradicted or elaborated upon by other descriptions set forth herein. Some of the terms set forth below may be registered trademarks (®).
bit The word “bit” is a shortening of the words “binary digit.” A bit refers to a digit in the binary numeral system (base 2). A given bit is either a binary “1” or “0”. For example, the number 100011 is 7 bits long. The unit is sometimes abbreviated to “b”. Terms for large quantities of bits can be formed using the standard range of prefixes, such as kilobit (Kbit), megabit (Mbit) and gigabit (Gbit). A typical unit of 8 bits is called a Byte, and the basic unit for 128 Bytes to 16 K Bytes is treated as a “page”.
BL short for bit line. The bit line is a conductor connected to the drain (or source) of a memory cell transistor.
byte A byte is commonly used as a unit of storage measurement in computers, regardless of the type of data being stored. It is also one of the basic integral data types in many programming languages. A byte is a contiguous sequence of a fixed number of binary bits. In recent years, the use of a byte to mean 8 bits is nearly ubiquitous. The unit is sometimes abbreviated to “B”. Terms for large quantities of Bytes can be fonned using the standard range of prefixes, for example, kilobyte (KB), megabyte (MB) and gigabyte (GB).
CHE short for channel hot electron CHE is an “injection mechanism” for injecting electrons into a charge storage area of an NVM memory cell.
CMOS short for complementary metal oxide semiconductor. CMOS consists of n-channel and p-channel MOS transistors. Due to very low power consumption and dissipation as well as minimization of the current in “off” state, CMOS is a very effective device configuration for implementation of digital functions. CMOS is a key device in state-of-the-art silicon microelectronics.
   CMOS Inverter: A pair of two complementary transistors (a p-channel and an n-channel) with the source of the n-channel transistor connected to the drain of the p-channel transistor and the gates connected to each other. The output (drain of the p-channel transistor) is high whenever the input (gate) is low and the other way round. The CMOS inverter is the basic building block of CMOS digital circuits.
   NMOS: n-channel CMOS.
   PMOS: p-channel CMOS.
EEPROM short for electrically erasable, programmable read only memory. EEPROMs have the advantage of being able to selectively erase any part of the chip without the need to erase the entire chip and without the need to remove the chip from the circuit. The minimum erase unit is 1 Byte and more typically a full Page. While an erase and rewrite of a location appears nearly instantaneous to the user, the write process is usually slightly slower than the read process; the chip can usually be read at full system speeds.
EPROM short for erasable, programmable read only memory. EPROM is a memory cell in which information (data) can be erased and replaced with new information (data).
Erase a method to erase data on a large set of bits in the array, such as by applying a voltage scheme that inrject holes in the bit set. This method causes all bits to reach a low Vt level.
FET short for field effect transistor The FET is a transistor that relies on an electric field to control the shape and hence the conductivity of a “channel” in a semiconductor material. FETs are sometimes used as voltage-controlled resistors The terminals of FETs are called gate, drain and source.
Flash memory Flash memory is a form of non-volatile memory (EEPROM) that can be electrically erased and reprogrammed. Flash memory architecture allows multiple memory locations to be erased or written in one programming operation.
Inhibit if it is desired to apply erase to a subset of bits, avoiding erase from other bits sharing the same bit lines (BLs), need to apply on the others a positive voltage on the gate, to avoid hole injection. This procedure is called inhibit.
MLC short for multi-level cell. In the context of a floating gate (FG) memory cell, MLC means that two bits of information can be stored in the memory cell. In the context of an NROM memory cell, MLC means that at least four bits of information can be stored in the memory cell.
MOSFET short for metal oxide semiconductor field-effect transistor. MOSFET is by far the most common field-effect transistor in both digital and analog circuits. The MOSFET is composed of a channel of n-type or p-type semiconductor material, and is accordingly called an NMOSFET or a PMOSFET. (The ‘metal’ in the name is an anachronism from early chips where gates were metal; modern chips use polysilicon gates, but are still called MOSFETs).
nitride commonly used to refer to silicon nitride (chemical formula Si3N4). A dielectric material commonly used in integrated circuit manufacturing. Forms an excellent mask (barrier) against oxidation of silicon (Si).
n-type semiconductor in which concentration of electrons is higher than the concentration of “holes”. See p-type.
NROM short for nitride read only memory.
NVM short for non-volatile memory. NVM is computer memory that can retain the stored information even when not powered. Examples of non-volatile memory include read-only memory, flash memory, most types of magnetic computer storage devices (for example, hard disks, floppy disk drives, and magnetic tape), optical disc drives, and early computer storage methods such as paper tape and punch cards. Non-volatile memory is typically used for the task of secondary storage, or long-term persistent storage. The most widely used form of primary storage today is a volatile form of random access memory (RAM), meaning that when the computer is shut down, anything contained in RAM is lost. Unfortunately most forms of non-volatile memory have limitations which make it unsuitable for use as primary storage. Typically non-volatile memory either costs more or performs worse than volatile random access memory. (By analogy, the simplest form of an NVM memory cell is a simple light switch. Indeed, such a switch can be set to one of two (binary) positions, and “memorize” that position).
ONO short for oxide-nitride-oxide. ONO is used as a charge storage insulator consisting of a sandwich of thermally insulating oxide, and charge-trapping nitride.
Over-erase a condition that happens to some bits in a large bit set that are erased together, due to erase speed difference, due to the situation that some bits erase faster than other bits. Fast bits are particularly susceptible to over-erase.
oxide commonly used to refer to silicon dioxide (SiO2) Also known as Silica. SiO2 is the most common insulator in semiconductor device technology, particularly in silicon MOS/CMOS where it is used as a gate dielectric (gate oxide); high quality films are obtained by thermal oxidation of silicon. Thermal SiO2 forms a smooth, low-defect interface with Si, and can be also readily deposited by chemical vapor deposition (CVD).
p-type semiconductor in which concentration of “holes” is higher than the concentration of electrons. See n-type. Examples of p-type silicon include silicon doped (enhanced) with boron (B), Indium (In) and the like.
PAE short for program after erase. PAE is useful to avoid cells that experienced over-erase and significant Vt reduction, to become leaky and cause read errors to all cells sharing the same Bit-lines.
Page Generally, a grouping of memory cells can be termed a word, a grouping of words can be termed a page, and a grouping of pages can be termed a sector. Data may be accessed for reading and programming (or writing) by word or by page, while an entire sector is commonly accessed for erasing.
PBE short for program before erase PBE is useful to bring cells to a more-or-less uniform level prior to performing an erase operation. Particularly, if a cell has been erased a number of times, it may otherwise end up with a negative Vt, which is generally undesirable.
Program a method to program a bit in an array, by applying a voltage scheme that injects electrons. This method causes an increase in the Vt of the bit. Alternatively, with high Vt erase, programming is a lowering of the Vt of the memory cell.
program rate as used herein, “program rate” refers to the number of times that a memoiy cell (or half cell) is programmed to various program (or threshold voltage) levels, such as representing a binary “1” or “0”.
Program time refers to the duration of a single program pulse, or the duration of the whole program sequence algorithm to program a bit set.
programmed “programmed” generally means that the threshold voltage (Vt) of a cell is above a predetermined “program verify” level (Vth).
PROM short for programmable read-only memory.
RAM short for random access memory. RAM refers to data storage formats and equipment that allow the stored data to be accessed in any order—that is, at random, not just in sequence. In contrast, other types of memory devices (such as magnetic tapes, disks, and drums) can access data on the storage medium only in a predetermined order due to constraints in their mechanical design.
Read read the digital data stored in the array.
Refresh a part of the program or erase algorithms that checks the status of bits and applies pulses to bits that may have lost some of their Vt due to reliability margin loss.
ROM short for read-only memory.
Sector a part of the array, usually larger than a page, which usually contains a few pages A minimum erase might include a sector.
Si Silicon, a semiconductor.
SLC short for single level cell. In the context of a floating gate (FG) memory cell, SLC means that one bit of information can be stored in the memory cell. In the context of an NROM memory cell, SLC means that at least two bits of information can be stored in the memory cell.
SONOS Si-Oxide-Nitride-Oxide-Si, another way to describe ONO with the Si underneath and the Poly gate on top.
TEHH short for Tunnel Enhanced Hot Hole injection. TEHH is an “injection mechanism”.
Units of Length Various units of length may be used herein, as follows:

meter (m) A meter is the SI unit of length, slightly longer than a yard. 1 meter=˜39 inches. 1 kilometer (km)=1000 meters=˜0.6 miles. 1,000,000 microns=1 meter. 1,000 millimeters (mm)=1 meter. 100 centimeters (cm)=1 meter.

micron (μm) one millionth of a meter (0.000001 meter); also referred to as a Micrometer.

mil 1/1000 or 0.001 of an inch; 1 mil=25.4 microns.

nanometer (nm) one billionth of a meter (0.000000001 meter).

Angstrom (Å) one tenth of a billionth of a meter. 10 Å=1 nm.
V short for voltage, Different voltages may be applied to different parts of a transistor or memory cell to control its operation, such as:

Vb short for bulk (or substrate) voltage

Vd short for drain voltage

Vg short for gate voltage

Vs short for source voltage

Vt short for threshold voltage
Verify a read operation after applying a program or erase pulse, that checks if the applied program or erase pulse moved the Vt to the target level (program-verify or erase-verify level).
WL short for word line. A word line (WL) is a conductor which is normally connected to the gate of a memory cell transistor.
Write a combined method of first erase a large set of bits, usually involving first erasing a laige set of bits, then programming new data into the bit set; the erase step is not required but it is customary.

### BRIEF DESCRIPTION (SUMMARY)

It is a general object of the disclosure to provide improved techniques for operating NVM memory cells.

According to the disclosure, generally, a balanced program rate on NVM cells may be achieved by (i) scrambling data bits and user bits; and (ii) shifting error detection (ED) bits (of data and user bits) according to an incremental shift number, which may be the PBE-counter (which provides an incremental number). ED bits for the last stored step (LSS) may also be shifted, according to an incremental shift number (which may be the PBE-counter). The ED bits of the shift-number inherently have an evenly balanced distribution. The ED bits of the PBE-counter inherently have an evenly balanced distribution. The shift-number and the PBE-counters also inherently have an evenly balanced distribution.

According to the disclosure, in a memory array having a plurality of memory cells for user data and a plurality of special memory cells for storing non-user data, a method of balancing (evening out) a programming rate for non-user data comprises: rotating a vector pointing to the special memory cells so that different ones of the special memory cells are used, rather than using the same special memory cells over and over. The vector may be rotated each time data is written for a different number of times before programming the non-user into the special memory cells. The vector may be rotated by programming either (1) an incremental number, or (2) a constant number that is (pseudo) randomly rotated. The vector may be rotated cyclically. The vector may be rotated according to an incremental number. The vector may be rotated by using a series with fewer than all of the bits changing at each step. The vector may be rotated by changing the data, but not the polarity of the bits, without inverting. The vector may be rotated according to a conversion table to locate the bits in a specific place in the vector. The vector may be rotated according to a shift number. The shift number may be provided by a program before erase (PBE) counter. Error detection (ED) bits may be generated and stored for the shift number. The shift number may be 2×−1 bits, where x can be any value higher then zero. ED bits may be programmed for a last stored step (LSS) with a cyclic shift. Any unused special cells may be programmed with a null pattern. The null pattern may be a changing pattern. The null pattern may be shifted along with shifting the vector. The null pattern may be shifted according to a program before erase (PBE) counter.

According to the disclosure, a method of achieving a balanced program rate on a plurality of NVM cells comprises: (i) scrambling data bits and user bits; and (ii) shifting error detection (ED) bits. The ED bits may be shifted according to an incremental shift number, and the incremental number may be a program before erase (PBE) counter.

### BRIEF DESCRIPTION OF THE DRAWINGS

Reference will be made in detail to embodiments of the disclosure, examples of which may be illustrated in the accompanying drawing figures. The figures are intended to be illustrative, not limiting. Although the disclosure is generally described in the context of these embodiments, it should be understood that it is not intended to limit the disclosure to these particular embodiments.

FIG. 1 is a stylized cross-sectional view of a field effect transistor (FET), according to the prior art. To the left of the figure is a schematic symbol for the FET.

FIG. 2 is a stylized cross-sectional view of a floating gate memory cell, according to the prior art. To the left of the figure is a schematic symbol for the floating gate memory cell.

FIG. 3 is a stylized cross-sectional view of a two bit NROM memory cell of the prior art. To the left of the figure is a schematic symbol for the NROM memory cell.

FIG. 4 is a diagram of a memory cell array with NROM memory cells, according to the prior art.

FIG. 5 is a diagram illustrating an implementation of the technique(s) of this disclosure, as relating to ED (error detection) cells.

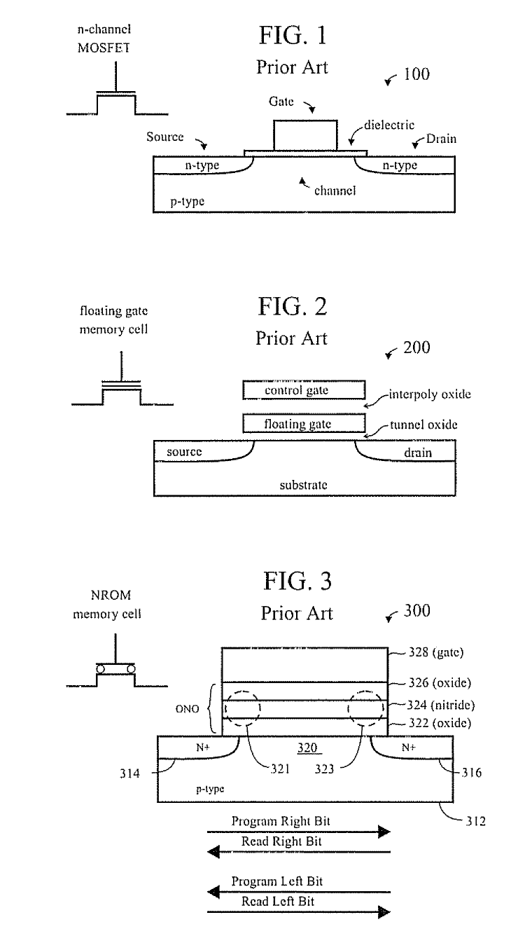

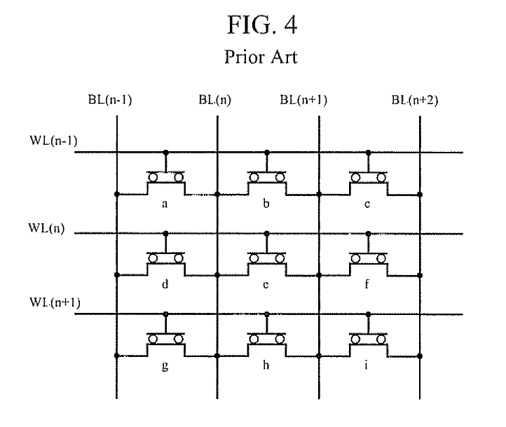

### DETAILED DESCRIPTION

In the following detailed description, numerous specific details are set forth in order to provide a thorough understanding of the disclosure. However, it will be understood by those skilled in the art that the teachings of the present disclosure may be practiced without these specific details. In other instances, well-known methods, procedures, components and circuits have not been described in detail so as not to obscure the teachings of the present disclosure.

### Introduction

This disclosure is generally related to the operation of a plurality of NVM memory cells, such as an array of NROM memory cells, and is particularly directed to the operating of programming, or writing data to the cells.

As a general proposition, the operation of writing requires an erase step (setting the cell(s) to a predetermined state), followed by a programming step (writing data into the cell(s)). For purposes of this disclosure, the term “write” is equivalent to its grammatical variant “writing”, the term “erase” is equivalent to its grammatical variant “erasing”, the term “progranm” is equivalent to its grammatical variant “programming”, and tlhe term “read” is equivalent to its grammatical variant “reading”.

For purposes of this disclosure, the program state of a memory cell is defined by a high threshold voltage (Vt), and the erase state of a memory cell is defined by a low Vt. With single level cell (SLC) operation, there are only these two levels (program or erase), representing either binary 0 or binary 1. (Associating binary 0 with program and binary 1 with erase is entirely arbitrary, and may be reversed). With multi-level cell (MLC) operation, there are various levels of programming (and erase) representing different binary numbers, such as 00, 01, 10, 11 (Binary 11 can represent “erase”).

For purposes of this disclosure, a memory cell includes any type of memory cell having a charge storage (or charge trapping) area, or areas Depending on the context, “memory cell” may refer to an entire floating gate memory cell, or half of an NROM memory cell having two distinct charge-trapping areas (“half cells”).

This disclosure relates to operating a plurality of memory cells (or half cells) which may be arranged in an array, having rows and columns, like a checkerboard. A single memory chip may contain several millions of memory cells. The techniques disclosed herein are generally applicable to any non-volatile memory (NVM) device where long term retention of electrical charges (electrons), frequently writing data, and the possibility of uneven programming may be an issue.

Generally, an array of memory cells can be subdivided, logically and/or physically, into “pages”.

In a typical (exemplary) memory array, a page may represent approximately 2 KB (over 2000 Bytes) of data.

A smaller section of memory is a “slice”. A slice may comprise 34 memory cells, which are:
32 “data cells” for user data bits (“data bits”);
1 “user cell” for additional user bits (“user bits”, which are similar to data bits); and
1 “special cell” dedicated to non-user data (NUD) such as enror detection (ED) bits and other special numbers. (One special cell can hold 1, 2, 4 or more bits, depending on the type of cell. Typically, an NROM memory cell holds 2 bits).

A megabyte (MB) of data, for example, comprises 8 million bits of binary data (ones and zeroes). Generally, one Byte generally equals eight bits, so one megabyte (1 MB) equals eight megabits (8 Mb).

In a single bit memory cell, such as a floating gate memory cell, storing 8 Mb of data would generally require 8 million memory cells. In a dual-bit memory cell, storing 8 Mb of data would generally require 8 million “half-cells”, or 4 million memory cells.

A single memory chip may contain several hundreds of millions of memory cells, and can typically store many user data files, such as photos and audio files. Often, many memory chips are interconnected in a “module” to provide even greater storage capability. For example, a typical RAM module for a personal computer has several individual memory chips mounted to a single printed circuit board.

A typical data file, such as a photo, may only require from a hundred thousand to a million Bytes of data to be stored. A typical data file, such as an MP3 song file, may only require a few million Bytes of data to be stored.

A problem with writing to (programming) memory cells is that as data (and new data) is written to a group of memory cells, individual ones of the cells may be programmed more (more times) than others. Such a lack of uniformity can cause difficulties when operating the memory cells, particularly with MLC operation of memory cells. In other words, if a given memory cell (or half cell) has been subjected to a different number of programming operations (injection of electrons to raise the thieshold voltage) than other cells, it can become “overprogrammed” and will tend to operate differently than other cells, and is likely to lead to problems in accurately reading the contents of the cell. A problem can also be encountered during the Erase operation: Non-programmed cells may get over-erased.

For example, depending on the data being written, over a plurality of program operations (cycles), a given memory cell (or half cell) may be programmed repeatedly with 0s, while another memory cell is programmed with a mixture of 0s and 1s, and yet another of the memory cells is programmed repeatedly with 1s. Non-uniformity means that the cells have not been programmed at an even program rate. Generally, two teclniques are luiown to overcome the problem of non-uniformity.

One solution to the problem is to perform program before erase (PBE) on all of the cells (or half cells) being erased. This procedure, referred to as “full PBE”, is simple and effective, and ensures an even program rate (uniformity). However, it takes a lot of time to perform the program operation (such as injection of electrons into the charge storage or trapping area of the memory cell). In addition to the “full PBE ” there is the option of “sparse PBE”, wherein each time a different group of cells is programmed.

Another solution to the problem is to scramble the data. This means changing ones to zeros in an organized manner so that all cells will be subject to the same number of 1's and 0's, within a statistically valid range This also ensures an even progran rate (uniformity). But since the data scrambling is independent of the actual program operation, there is essentially no negative impact on the program operation, just a small overhead required to scramble the data.

Data scrambling is already defined, and may be achieved by doing an invert on each bit, according to a scrambling pattern. When being read, the data is unscrambled, using the same pattern. The pattern is the “key”.

Data scrambling ensures a more even distribution of Is and Os being written (“even program rate”), even if the data for a given cell (or half cell) is repeatedly being written at one programming level (usually a binary 0). For example, if a given memory cell (or half cell) is being targeted for programming repeatedly with binary 0 (due to the data for that bit being programmed not changing over a number of program cycles), data scrambling will cause it to be programmed sometimes with a 0 and sometimes kept erased as 1. For purposes of this disclosure, this is referred to as “evening out the programming rate”. (In this case, “rate” is not speed. Rather, it is a statistical distribution. The goal of data scrambling is to make uniform the number of times that a given cell or half-cell is programmed to a given program, or voltage, level). Another way of referring to such data scrambling is “balancing the content to be programmed”, or “balancing the programming rate”.

A typical data scrambling is a “mirror series” in which numbers are incremented (for example, 0, 1, 2, 3, 4 . . . and so forth, which in binary is 00000000, 00000001, 00000010, 00000011, 00000100 . . . and so forth, from 0 to n), and following every incremented number, its “mirror” is inserted where every digit it inverted, resulting, for example, in a sequence, as follows (a “truth table” for an 8 bit binary number is illustrated):
incremental number mirror (‘1’ means “invert”)
00000000, followed by 1111111 (the inverse of 00000000), followed by
00000001, followed by 11111110 (the inverse of 00000001), followed by
00000010, followed by 11111101 (the inverse of 00000010), and so forth.

According to the above, the first time a number is written (programmed), it is written without any scrambling (as indicated by 00000000, no digits are inverted). The next time (next program cycle), it is written with all of its digits inverted (as indicated by 11111111, all 8 digits inverted). The next time, it is written with one digit inverted (as indicated by 00000001, the least significant bit is inverted). The next time, it is written with seven digits inverted (as indicated by 11111110, the 7 most significant bits are inverted). And so forth.

For purposes of this disclosure, the concept of scrambling is only applied to “user data”, as described hereinbelow.

A nuance of operating a memory array is that in addition to storing user data, additional non-data (or non-user data, “NUD”) bits are stored representing special information which is related to the user-data, such as error detection (ED) bits which are used to verify that user data has not been corrupted.

In a manner similar to how memory cells (or half cells) can be adversely affected by uneven programming rates for user data, the same problem can result from uneven programming rates for the non-user data (NUD) memory cells.

Generally, for purposes of this disclosure, user data is stored in one section of memory, in a given plurality of memory cells (or half cells), and non-user data, such as error detection (ED) bits are stored in another section of memory, in other memory cells (or half cells) which may be referred to herein as “special cells”.

The NUD is special information related to the user data, which is maintained internally, in the memory chip, and which may comprise not only ED bits, but also other information such as PBE counter, LSS, shift-number, described in greater detail hereinbelow.

For purposes of this disclosure, ED bits are discussed as representative examples of any NUD, As used herein, NUD may include such things as: PBE counter, LSS, shift-number for the data scrambling pattern, and any data that cannot be scrambled.

Generally, two special non-data (NUD) types are: (i) any data that cannot be scrambled (for example the ED bits), and (ii) any data that cannot be scrambled or cyclically shifted (for example the cycle counter (=PBE counter)).

This disclosure addresses (solves) the problem of obtaining an even program rate for NUD, While scrambling user data is an acceptable solution for obtaining an even program rate for user data, generally speaking, NUD bits cannot be scrambled Otherwise, they would lose their veracity and utility. And, as mentioned before, although performing fiull PBE ensures an even program rate, it is time-consuming.

Therefore, a problem exists as to how to even out the programming rate for the memory cells storing NUD bits, without performing scrambling or full PBE.

According to the disclosure, generally, the problem of evening out the programming rate for memory cells storing NUD bits may be solved by rotating (or shifting) the data pattern (vector) each time for a different number of times before programming it into the special cells designated for NUD. This means that a given NUD is written to different cells (or half cells) within a set of special memory cells so that an even probability exists of a given cell (or half cell) being programmed at different program levels in each subsequent program cycle, thereby avoiding the problem associated with repeatedly programming a given cell (or half cell) at a given program level over a sequence of program cycles.

Therefore, even if a user inserts the same data over and over, resulting in the same special numbers (NUD, such as ED bits) being calculated for the user data—different cells within the group of special cells will be programmed each time, ensuring an even programming rate. An advantage of this solution is its simplicity together with its high probability for a different pattern each time.

When writing user-data, the same cells are used over and over for NUD (such as ED bits). The cells that are being used to store NIUD are located by a vector, which is essentially a pointer pointing to where the cell containing NUD is located.

Generally, the programming rate for memory cells containing NUD can be evened out simply by changing or alternating or shifting, such as rotating the vector, each time user-data is being written, so that different memory cells can be used, rather than using the same memory cells over and over. The general idea here is not to have the same vector used over and over without it being changed. One simple way to get a different vector each time is by a rotation. There are other ways to get a different vector each time, such as alternately mirroring the vector (resulting in 2 different vectors), or using any other mathematical function. As used herein, “rotating” may be interpreted to include (be representative of) any form of changing or alternating the vector.

Thus, in the long run each special memory cell (SMC) will have an even rate (probability) of being programmed or not This is achieved by programming either (1) an incremental number, or (2) a constant number that is (pseudo) randomly rotated.

According to this disclosure, the problem is solved by rotating (changing, alternating, shifting) the data pattern (rotating or changing the vector) each time data is written for a different number of times before programming the NUD into the special (NUD) cells. So, even if the user inserts the same data and same special numbers are calculated—different cells will be programmed each time. The advantage of this solution is its simplicity together with its high probability for a different pattern each time.

This disclosure addresses the problem of a non-even programming rate for special cells. Even in cases where the same ED bits are generated each time (repeatedly, over subsequent program cycles), rather than the same special memory cells being programmed with the same ED bits, different special memory cells are programmed.

In a memory array comprising a plurality of memory cells for user data, and a plurality of memory cells for non-user data (NUD), the techniques disclosed herein provide an even programming rate over the special (for NUD) memory cells in the array. Having an even programming rate improves memory chip cycling performance and/or reliability.

The teclniques disclosed herein for rotating (shifting) the NUD can advantageously be used in conjunction with conventional techniques for scrambling user data, to ensure an even program rate across the entire memory array.

In brief, user data is scrambled, before being programmed into the memory cells designated for user data, and any non-user data (NUD) that is being programmed into the special memory cells is rotated/shifted (but the NUD itself is not changed, or scrambled) every “X” number of program plus erase cycles.

“X” can be 1 (in which case, the NUD vectors are changed each and every time there is a program cycle. Or, “X” may be a number greater than 1, such as 8 or 16, and will still yield the desired result (within acceptable statistical variations).

Generally, “X” should be kept as low as possible, In a real incremental number—the Least Significant Bit (LSB), (in the one's place) would change polarity every cycle, but the Most Significant Bit would change polarity only every 64 cycles (for a 7 bits counter). So, instead of a real incremental number (where the MSB has the worst rate case) use a different encoding where all/most NUD bits changes each cycle. For example, instead of a simple incremental series {0000000, 0000001, 0000010, . . . } use a mirror like series {0000000, 1111111, 0000001, 1111110, . . . }.

The programmed non-user data (NUD) is either (1) cyclically shifted according to an incremental number, or (2) the incremental number (such as with a mirror like series), In either case, each program command will have a different number of bits rotated, even if the user inserts the same user data, and the same ED bits are calculated for the user data.

An even program rate on user data is achieved by the data scrambling operation (bitwise XOR with a scrambling pattern). There is the non-user data (NUD) which can't be scrambled. The NUD currently contains two types of data: (1) ED bits (2) incremental number. An even program rate on the NUD may be achieved by (1) cyclicly rotating the ED bits, or (2) using a mirror like series instead of an incremental number.

There are at least two special non-data (NUD) types, One is error detection (ED), which is cyclically shifted. The other type is an incremental number that will not be cyclically shifted—it does not need to be—just fiom being an incremental (changing every cycle, by an increment), different bits are programmed each time.

As mentioned above, two non-data (NUD) types are: any data that can't be scrambled (for example the ED bits), and the other type is any data that can't be scrambled or cyclically shifted (for example the cycle counter (=PBE counter)).

With X as low as possible, a simple internal sequence is not used, but rather the sequence may be (0, mirror, 1, mirror, . . . ).

It is within the scope of this disclosure that, instead of applying a mirror or a minror like series to rotate the NUD vector, a different series (or sequence) with fewer than all of the bits changing at each step, and/or having a different start value can be used, For example, a half mirror, generated on the fly (example, 00000000, 00001111, 00000001, 00001110 . . . ), or a mirror starting at other than 0 (example, 00001000, 11110111, 00001001, 11110110 . . . ).

It is within the scope of this disclosure that, for rotating (such as shifting, changing, alternating) the NUD vector, instead of using a cyclic shift, a different (and more complex) transformation can be used, such as changing the data, but not the polarity of the bits, without inverting; or, according to a conversion table to locate (map) the bits in a specific place in the vector.

### A More Detailed Description, and Examples

As mentioned above, in a typical (exemplary) memory array, a page may represent approximately 2 KB (2000 Bytes) of data. A smaller section of memory is a “slice”, which may comprise 34 memory cells, which are:
32 “data cells” for user data bits (“data bits”);
1 “user cell” for additional user bits (“user bits”, which are similar to data bits); and
1 “special cell” dedicated to non-user data NUD) such as error detection (ED) bits and other special numbers. (One special cell can hold 1, 2, 4 or more bits, depending on the type of cell. Typically, an NROM memory cell holds 2 bits,)

All of the cells (or half-cells), including data cells, user cells and special cells in a memory array should have an equal program rate in order to avoid the need of PBE for erase pages without having over-erased cells.

For data bits and user bits there is the data-scrambling concept to ensure an equal program rate to all data cells and user cells.

For each program command, a different data pattern scrambled is programmed, even if a user enters the same data. In other words, for each Program command, a different shift number is used. Although there may not be an infinite number of possible shift numbers, there are enough so they will not be repeated too often. This shift number cycle rotates the scrambling pattern, thus forming a different scrambling pattern for each program command, This results in a different scrambled data to be programmed in the array, even if user enters the same data in each program command.

Data is typically scrambled according to a constant pattern (of 64 bits) that is kept in OTP (one time programming) and loaded in power-up. The data scrambling pattern is an OTP data which is set by the manufacturer, and cannot be erased by the user. Inasmuch as OTP is programmed only once, achieving an even programming rate is not an issue.

In order to have a different scrambling pattern the constant pattern has a cyclic shift.

The number of bits being cyclic shift is done according to a shift-number.

The shift-number is randomly generated for each new program command.

The shift-number value may be 0-63 (in which case, 6 bits would be needed).

By way of example:

Two kilobytes (“2 kB”, or 2112 Bytes) of memory may be divided into four “user” chunks of 528 B each, as follows:
4×528 B=2112 B

Each user chunk may further be divided into four “rd” (read) chunks as follows:
128 B+128 B+128 B+144 B=528 B

If each Byte (B) equals 8 bits (b), the four rd chunks calculate as:
1024 b+1024 b+1024 b+1152 b

The size of the rd chunks is arbitrary, and is selected to be of somewhat small size to reduce the probability of read errors. Read errors are typically determined, as follows:
for each “rd” chunk (of 128 B or 144 B), the number of 0's (or 1's) is counted; or
more generally, since each cell (or half cell) can be programmed with two bits (00, 01, 10 or 11) rather than counting the number of 0s, the number of cells (or half cells) at a certain program level (which may be any of 00, 01, 10 or 11) can be counted.

The number of ‘0’s, named as ED (error detection) bits, is stored in the array along with the page. Special memory cells are set aside for these NUD bits.

During a read command, the ED bits are read with the “rd” chunk. The number of 0's (or number of cells at a certain program level) in the read data is counted. A read error is identified to each “rd” chunk by comparing ED bits with number of ‘0’s (or number of cells at a certain program level) in the read data.

For the exemplary read chunks, the ED bits should be able to count from 0 up to 1,024 (or up to 1,152). Therefore, there needs to be 11 ED bits for each read chunk (1024=10000000000, or 11 bits, in binary notation. 1152 in decimal notation equals 10010000000, or 11 bits, in binary notation).

The rd-chunk itself (which contains only user data) is divided into addresses, and the data in each address is scrambled. The ED bits of all rd-chunks are stored together in special extra addresses, and in each address the ED bits of each rd-chunk are shifted around separately.

By way of example, there may be 256 half cells in each Array address, and all ED bits of all rd-chunlcs and all special numbers may be located together in 2 consecutive Anay addresses.

Totally, 16 [rd chunks]×11 [bits/chunk]=176 bits are needed for ED bits per page.

Additionally, one cell is added per slice sense amplifier (SA). (There can be more than one slice for each sense amplifier, or there may be one sense amplifier per slice).

Totally, 256 cells are added per 2 KB page 2[b/c]×256[cells]=512 bits “b/c” is short for bits per cell, sometimes it may be referred as “bpc”

176 half cells out of the 512 half cells are used to store the ED bits (of data).

As mentioned above, the data scrambling concept ensures different data, but it doesn't ensure a different counted number of 0's program-levels (ED bits) for the NUD. The ED bits might not change between pages, thereby causing the same half cells being not programmed (in the program command) and only being erased (in the erase command).

The ED bits are not scrambled

As mentioned above, the ED bits cannot be scrambled.
If there is a retention (‘0’ becomes ‘1’) on the ED bits and on the data bits, the ED bits value must show a larger number of ‘0’s while the number of ‘0’s counted from the read data is, of course, smaller;
Scrambling the ED bits will not allow the statement above
Same principal for a 2nd bit effect (only different directions)

Assume the data being programmed (after the scrambling) is of 7 bits—“1110000”. The ED bits programmed are “100” (the decimal value of this binary number is 4). Now, assume there is a retention phenomenon in Array (meaning a read error because a ‘0’ in Array is wrongly read as ‘1’). The retention can affect only the data, only the ED bits, or both of them. Assume that it affects both of them. In this case we might wrongly read the data as “1110001” and the ED bits as “101”. In such a case we discover there is an error because there are 3 ‘0’s in the read data while the ED bits claim there should be 5. In this case, we not only know that there is an error, we also lcnow that we read from the Array less ‘0’s than there should be (data has 3 ‘0’s while ED claim there should be 5). This information is needed in order to make some fix in the read algorithm and read again from Array.

If we were to scramble the ED bits, they may be programmed to any value. For example they may be programmed to “000” (a value after scrambling). After retention we might read them wrongly as “001” (‘0’ became ‘1’). In such case there are 3 ‘0’s in the read data (“111000”) but ED bits claim there should be only one ‘0’. So we get a wrong conclusion that we read from the Array more ‘0’s than what should be (data has 3 ‘0’s while ED claim there should be 1).

Another example is if the ED bits are scrambled to be “010” and after retention we read “011”. Here the ED bits match the wrong read data of “1110001” and no error will be detected.

Therefore, the ED bits must not be scrambled.

Shift-number, and ED bits for the Shift Number

“PBE” stands for program before erase, and means that programming is done before an erase. Programming may be done before each erase. Or, programming can be done before some number (such as 2, 4, 8) erases. In either case, there is typically a PBE counter which marlks every erase cycle.

As mentioned above, the ED bits for data are not scrambled. Rather, they are shifted. The ED bits may be cyclically shifted according to a shift-number. Shifting the ED bits will guarantee an equal program rate for them.

The shift-number (for shifting the ED bits) may simply be provided by the PBE counter. Alternatively, another counter that increments in the same way, or in a different way can be used to provide the shift number.

Optionally, ED bits may be generated (and stored) for the shift-number itself, to guarantee its correctness. These ED bits can't be scrambled (as shown for data). And, these ED bits can't be shifted, because then the shift-number will be needed for reading them, which would create a conflict.

The ED bits of the shift-number will be balanced (have an even prograin rate) as follows:
Assume that the shift-nutmber is 6 bits (the PBE counter can count from 0 to 127)
Counting the number of ‘’s on all 6 bits will result in a number between 0-6. The counted number of ‘0’s is an histogram with middle option (3) with most likely probability, therefore an unbalanced program rate between the bits
Solution: Programming a shift-number that is 7 bits (but only 6 will be used to shift the scrambling pattern)
mirror series (even program rate), shift number+ED bits (also equal program rate)
7th bit, just increment from 6 to 7.

The reason for 7 bits is, as follows:

If shift-number of 6 bits then its ED bits can be any of the following values (0-6):
000 001 010 011 100 101 110

Most likely (for mathematical reasons) the number of ‘0’s counted will be the middle value of 011. So the MSB of the ED bits will be programmed in higher rate then the 2 LSBs.

If shift-number of 7 bits then its ED bits can be any of the following values (0-7):
000 001 010 011 100 101 110 111
   most likely (for mathematical reasons) the number of ‘0’S counted will be one of the two middle values of 011 or 100. Note that these are mirror values, so all bits get programmed in the same rate.

The counted number of ‘0’s is now 0-7 with an even histogram resulting with an even chance to be programmed to all bits. The number of bits for the shift number is 3 (to count to 7).

The counted number of ‘0’s of a 7 bits shift number can vary from 0 (if shift number is “1111111”) to 7 (if shift-number is “0000000”). Therefore, in order to be able to count the number of ‘0’s in a 7 bits shift number, a 3 bits number is needed to count from 0 (“000”) up to 7 (“111”). This counter (which is ED bits of the shift number) has 8 different options in which 4 options are mirror to the other 4 options. Therefore, the ED bits of the shift number also have an even program rate.

It can therefore be seen that the simplest way to have ai even program rate on the ED bits of the shift-number is to have a shift-number of 2^{x}-1 bits, where x can be any value higher then zero. In the example above, it is 2³-1=7 bits.

PBE counter

The PBE counter is incremented by one each erase cycle. Therefore, its bits (the memory cells dedicated to the PBE counter) are balanced (evenly programmed).

The PBE counter is also 7 bits, but only the 3 least significant bits (LSB) may be used in the PBE algorithlm.

The counted number of ‘0’s is 0-7, so its ED bits has a balanced program rate too. (The ED bits of the PBE counter are also NUD, but they need not be shifted, because they are balanced like ED bits of shift-number, as explained above).

If the PBE counter will be just incremented its most significant bit (MSB) can be erased consecutively for 64 times without being programmed.

Solving this problem is by decoding a PBE counter as follows (using a mirror series):

| read op | sw trans |
|---|---|
| 0000000 => (inv) | 1111111 |
| 1111111 => (inv + 1) | 0000001 |
| 0000001 => (inv) | 1111110 |
| 1111110 => (inv + 1) | 0000010 |
| 0000010 => (inv) | 1111101 |
| 1111101 => (inv + 1) | 0000011 |

### Last Stored Step (LSS)

The LSS (Last Stored Step for VPPD/VCVP) have a cyclic shift according to the PBE cotnter.

VPPD is the drain voltage during erase and VCVP is the gate voltage during erase. As related to the present disclosure, it is simply useful to note that there are special numbers that are not counters and actually can be regarded like constants (or almost constants) that are also part of the NUD.

The ED bits of the LSS also have a cyclic shift according to the PBE counter.

Unused half cells and Null Pattern

In the course of programming, it is not uncommon that fewer than all of the cells (or half cells) in a given read block may be programmed, resulting in memory cells (or half cells) that are “unused”.

Any unused half cells must be programmed as well and in a similar program rate.

The unused half cells will be programmed according to a constant pattern, named as “null-pattern”. Any pattern can be used, and it should be a changing pattern.

The unused cells being mentioned here are in the NUD section. But they can be in the user data as well, For purposes of this disclosure, the null pattern is part of the NUD.

According to a feature of the disclosure, in order to program a different pattern each time, the “null-pattein” is shifted, As was the case with shifting the vector for NUD, the null pattern may also be shifted according to the PBE counter. In other words, some NVM half-cells are not used at all (they are not used for user data and they are not used for non-user data storage). Nevertheless, these half-cells should not be left erased for each Progam+Erase cycle. Rather, they should also be programmed in an even program rate during the Program commands. These unused half-cells may be programmed with a constant pattern (referred as Null Pattern) that has a cycle shift each Program command. This way these unused half-cells are programmed with a different data pattern each Program command (within a cycle).

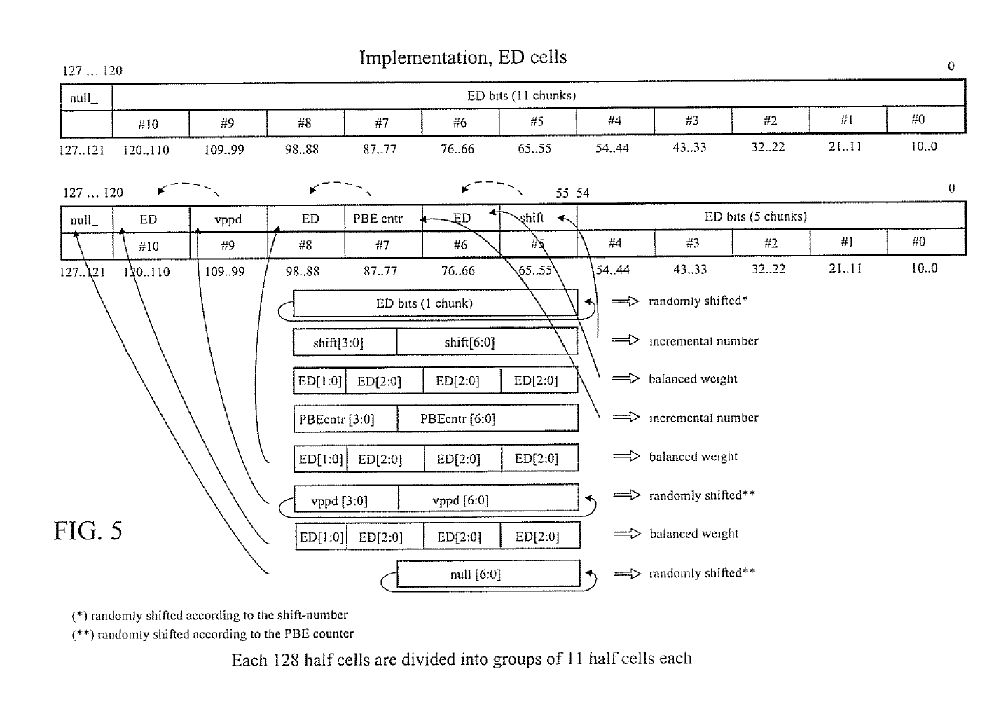

In the provisional patent application, at pages 17, 18 and 19, there are three drawings illustrating some of the techniques of the present disclosure. FIG. 5 herein corresponds to page 17.

FIG. 5 is a diagram illustrating an implementation of the technique(s) of this disclosure, as relating to ED (error detection) cellsn This figure shows one option of how to locate the NUD bits within the extra Array cells. It also illustrates for each special number (ED, Shlift-number, PBE-counter, . . . ) how an even program rate is achieved—by either a random shift, being an incremental number or by having a balanced weight.

For example FIG. 5 shows how an even program rate is achieved on 256 (128+128) half-cells of NUD. The 256 half-cells are segmented to (divided into) groups of 11, except for the last group in each 128 which may have only 7 half-cells). This segmentation of 11 half-cells is derived fiom the internal division of the page to rd-chunks that require 11 ED bits to each rd-chvunk. Each segment of 11 half-cells is used for storing one type of NUD and has an even program rate over its half-cells. FIG. 5 shows the layout of the segments, and illustrates how an even program rate may be achieved: (1) ED bits—have a cyclic internal shift according to the shift number, (2) the shift number itself is an incremental number of 7 bits size. The other 4 (of 11) bits are a duplication of the 4 LSB of the shift number itself. (3) ED bits of the shift number have a balanced weight to each of 8 possible options and are duplicated to fill all 11 bits. (4)+(5) The PBE counter and its ED bits are balanced like the shift number and its ED bits. (6) The VPPD value has a cycle shift and is also duplicated to fill all 11 bits segment. (7) ED bits of the VPPD value have a balanced weight to each of 8 possible options and are duplicated to fill all 11 bits. (8) Any unused segmentation is programmed with a null pattern that also has a cycle shift.

While a number of exemplary aspects and embodiments have been discussed above, those of skill in the art will recognize certain modifications, permutations, additions and sub-combinations thereof. It is therefore intended that the following appended claims and claims hereafter introduced be interpreted to include all such modifications, permutations, additions and sub-combinations.

What is claimed is:

1. In a memory array having a plurality of memory cells for user data and a plurality of special memory cells for storing non-user data, a method of balancing a programming rate for non-user data comprising:
shifting a vector pointing to the special memory cells so that different ones of the special memory cells are used, rather than using the same special memory cells over and over.

2. The method of claim 1, further comprising:
shifting the vector each time data is written for a different number of times before programming the non-user data into the special memory cells.

3. The method of claim 1, further comprising:
shifting the vector by programming either (1) an incremental number, or (2) a constant number that is (pseudo) randomly rotated.

4. The method of claim 1, wherein:
the vector is rotated cyclically.

5. The method of claim 1, wherein:
the vector is shifted according to an incremental number.

6. The method of claim 1, wherein:
the vector is shifted by using a series with fewer than all of the bits changing at each step.

7. The method of claim 1, wherein:
the vector is shifted by changing the data, but not the polarity of the bits, without inverting.

8. The method of claim 1, wherein:
the vector is shifted according to a conversion table to locate the bits in a specific place in the vector.

9. The method of claim 1, wherein:
the vector is shifted according to a shift number.

10. The method of claim 9, wherein:
the shift number is provided by a program before erase (PBE) counter.

11. The method of claim 9, further comprising:
generating and storing error detection (ED) bits for the shift number.

12. The method of claim 9, wherein:
the shift number is 2x-1 bits, where x can be any value higher then zero.

13. The method of claim 1, further comprising:
programming ED bits for a last stored step (LSS) with a cyclic shift,

14. The method of claim 1, further comprising:
programming any unused special cells with a null pattern.

15. The method of claim 14, wherein:
the null pattern is a changing pattern.

16. The method of claim 14, wherein:
the null pattern is shifted along with shifting the vector

17. The method of claim 14, wherein:
the null pattern is shifted according to a program before erase (PBE) counter.

18. A method of achieving a balanced program rate on a plurality of NVM cells comprising:
(i) scrambling data bits and user bits; and
(ii) shifting error detection (ED) bits.

19. The method of claim 18, wherein:
the ED bits are shifted according to an incremental shift number.

20. The method of claim 18, wherein:
the incremental number is a program before erase (PBE) counter.
